(19) United States
(12) Patent Application Publication
(10) Pub. No.: US 2018/0108560 A1
(43) Pub. Date: Apr. 19, 2018

(54) SUBSTRATE HOLDER

(71) Applicant: CORNING INCORPORATED, CORNING, NY (US)

(72) Inventors: Daniel Robert Boughton, Naples, NY (US); James Gerard Fagan, Painted Post, NY (US); Valerie Elise Mebert, Corning, NY (US); Kenneth Spencer Morgan, Painted Post, NY (US)

(21) Appl. No.: 15/568,875

(22) PCT Filed: Apr. 22, 2016
(86) PCT No.: PCT/US16/28795

§ 371 Date: Oct. 24, 2017

Related U.S. Application Data
(60) Provisional application No. 62/152,191, filed on Apr. 24, 2015.

(51) Int. Cl. H01L 21/687

(52) U.S. Cl. CPC H01L 21/68728; C23C 14/50; H01L 21/68735

(57) ABSTRACT

Substrate holders having support plates for mounting of substrates are disclosed. The substrate holders use a combination of spring clamping elements and pins to grip the substrates. The substrate edge contact height of the spring clamping elements and pins may be selected such that upper portions of the side edges of the substrates are substantially unobstructed, allowing coating to be applied to upper surfaces and upper portions of the side edges of the substrates contemporaneously.

### CROSS-REFERENCE TO RELATED APPLICATIONS

This application claims the benefit of priority under 35 U.S.C. § 119 of U.S. Provisional Application Ser. No. 62/152,191 filed on Apr. 24, 2015, the content of which is relied upon and incorporated herein by reference in its entirety.

### BACKGROUND

One of the main challenges in coating a substrate is how to support the substrate during the coating process. Adhesive, mechanical, vacuum, and electrostatic methods for mounting substrates to a coating platform are known. Adhesive methods introduce an extra step of removing adhesive residues from the substrate after the coating. Mechanical methods typically involve use of clamps, clips, and the like to grip the sides of the substrate. Typically, these gripping elements are used in such a way that they cover areas of the substrate to be coated. Vacuum clamping may be ineffective if the coating is carried out in high vacuum. Electrostatic clamping typically does not suffer from the challenges of the other clamping methods, but the capital cost of electrostatic clamping equipment can be prohibitive.

### SUMMARY

Substrate holders for holding substrates in a secure manner for coating and other applications are disclosed. The substrate holders can grip the substrates in a manner that would not involve covering the surfaces of the substrates to be coated.

In one illustrative embodiment, a substrate holder includes a support plate having a substrate mounting area and at least two spring members coupled to the support plate such that at least a portion of the substrate mounting area is between the two spring members. The two spring members are arranged relative to the substrate mounting area to engage side edges of a substrate and apply opposing forces to the substrate when the substrate is mounted on the substrate mounting area.

In another illustrative embodiment, a substrate holder includes a support plate having a substrate mounting area, a spring member coupled to the support plate, and a contact pin coupled to the support plate such that at least a portion of the substrate mounting area is between the spring member and the contact pin. The spring member and contact pin are arranged relative to the substrate mounting area to engage side edges of a substrate and apply opposing forces to the substrate when the substrate is mounted on the substrate mounting area.

### BRIEF DESCRIPTION OF THE DRAWINGS

The following is a description of the figures in the accompanying drawings. The figures are not necessarily to scale, and certain features and certain views of the figures may be shown exaggerated in scale or in schematic in the interest of clarity and conciseness.

FIG. 1A shows a substrate mounted in a substrate holder according to one embodiment.

FIG. 1B shows a substrate holder using flat springs as clamping elements.

FIG. 1C shows a vertical cross-section of the substrate holder of FIG. 1B.

FIG. 1D shows an example of a cantilever spring.

FIG. 1E shows a substrate having straight side edges mounted in the substrate holder of FIG. 1B.

FIG. 1F shows a substrate having beveled side edges mounted in the substrate of FIG. 1B.

FIG. 2A shows a substrate holder using a torsion spring and contact pins as clamping elements.

FIG. 2B shows a substrate mounted in the substrate holder of FIG. 2A.

FIG. 2C shows a side view of the substrate holder of FIG. 2A.

FIG. 3A shows a substrate holder using lateral spring pins and contact pins as clamping elements.

FIG. 3B shows an example of a lateral spring pin.

FIG. 3C shows a substrate mounted in the substrate holder of FIG. 3A.

FIG. 4A shows a substrate holder using lateral springs and a contact pin as clamping elements.

FIG. 4B shows a substrate mounted in the substrate holder of FIG. 4A.

FIG. 5A shows a substrate holder using spring energized seals as clamping elements.

FIG. 5B shows a spring energized seal.

FIG. 5C shows a substrate mounted in the substrate holder of FIG. 5A.

FIG. 5D shows a side view of the substrate holder of FIG. 5A.

FIG. 6A shows a substrate holder using contact pins and a spring loaded plunger as clamping elements.

FIG. 6B shows a substrate mounted in the substrate holder of FIG. 6B

### DETAILED DESCRIPTION

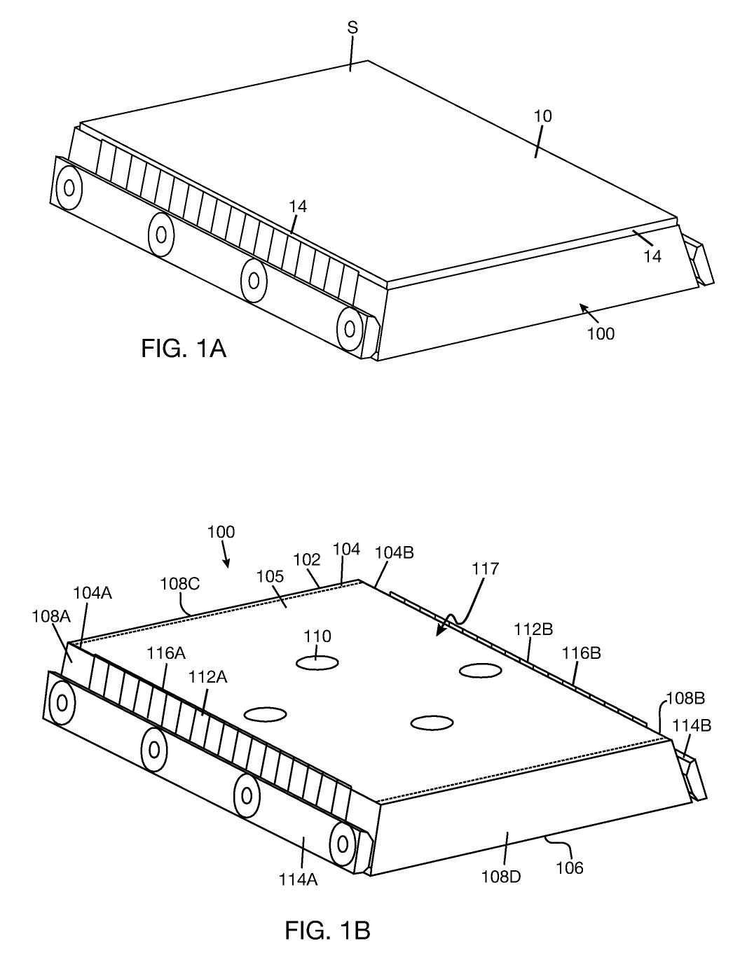

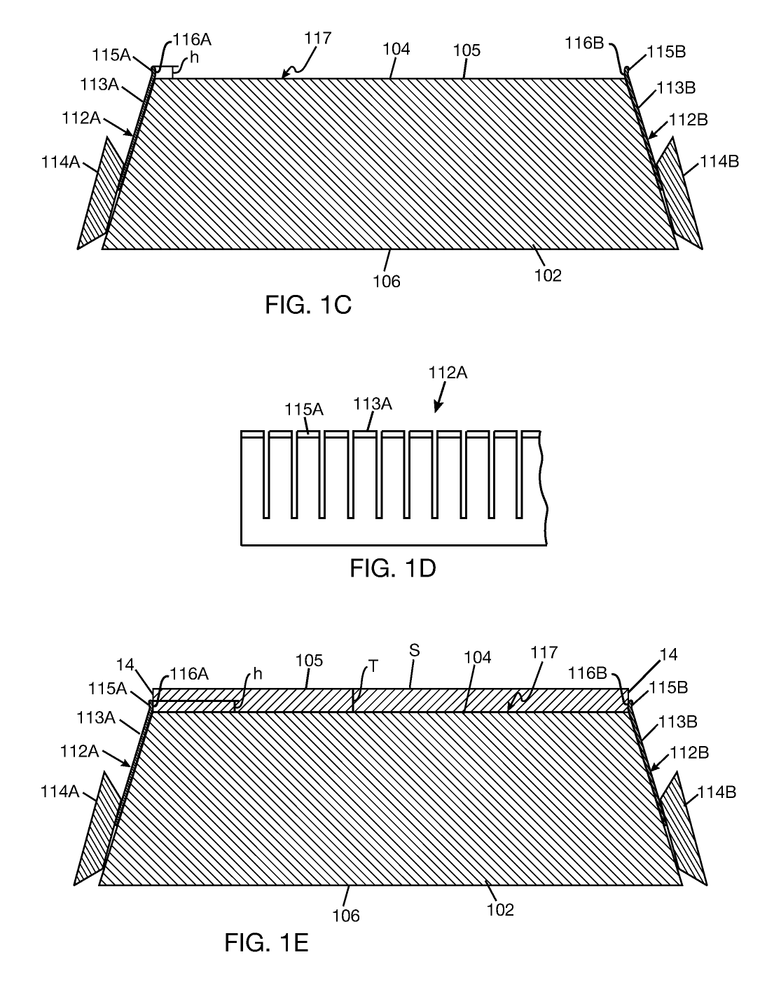

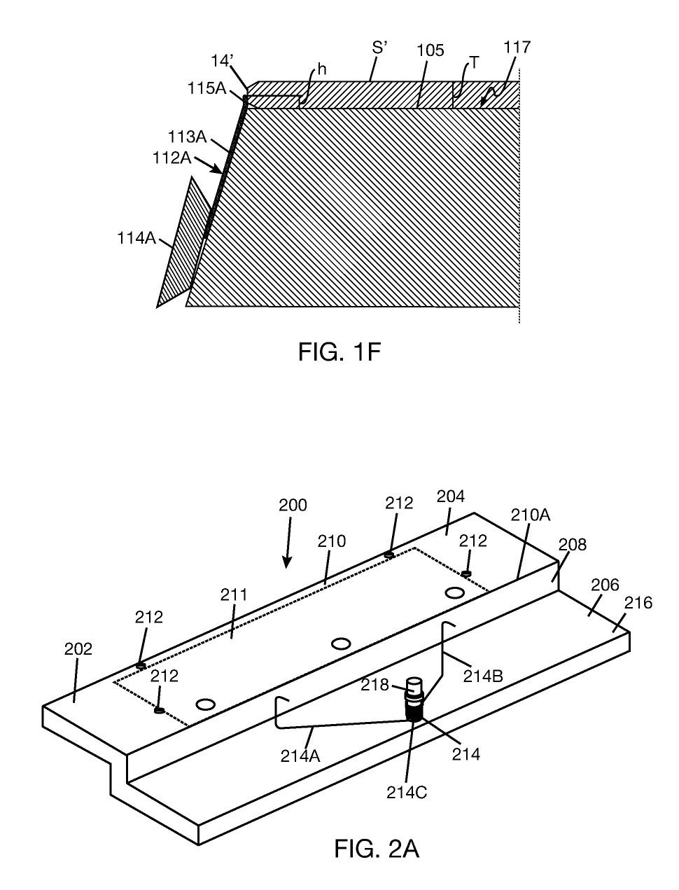

FIG. 1A shows a substrate S mounted in a substrate holder 100. The design of the substrate holder 100 is such that a top surface 10 of the substrate S and at least an upper portion of the side edges 14 of the substrate S are unobstructed or uncovered. The substrate holder 100 may be used in any coating application where it is desired to support a substrate in such a way that the top surface and at least an upper portion of the side edges of the substrate are unobstructed. The substrate holder 100 may be used in any thin film coating process, such as physical vapor deposition, plasma-enhanced vapor deposition, and the like. As shown in FIG. 1A, the substrate holder 100 will allow the top surface 10 and upper portion of the side edges 14 of the substrate S to be fully coated with a coating material. To apply a coating to the bottom surface and lower portion of the side edges 14 of the substrate S, the substrate S can be unmounted from the substrate holder 100 and remounted such that the bottom surface becomes the top surface and the lower portion of the side edges becomes the upper portion of the side edges.

Referring to FIG. 1B, the substrate holder 100 includes a support plate 102 having a top surface 104, a bottom surface 106, and sidewalls 108A, 108B, 108C, 108D. The top surface 104 has an area 105 for mounting of a substrate. The substrate mounting area 105 may occupy the entire top surface 104 or just a portion of the top surface 104. If desired, the area 105 may be expanded to accommodate multiple substrates. While the substrate is mounted on the substrate mounting area 105, the support plate 102 can provide thermal cooling to the substrate by conducting heat away from the substrate. The flatness of the substrate mounting area 105 is important to preventing deformation of the substrate when the substrate is mounted on it. In one embodiment, the substrate mounting area 105 may have a flatness in a range from 0.0005 inch to 0.001 inch TIR. TIR, total indicator reading, is the difference between maximum and minimum measurements of a surface, showing the amount of deviation of the surface from a reference surface. Herein, flatness is a measure of how well the substrate mounting area 105 conforms to the mating substrate surface, and the numerical value of flatness may be a measurement of the largest gap at the interface between the substrate mounting area 105 and the mating substrate surface. Therefore, specifying that a substrate mounting area 105 should have a certain flatness does not necessarily mean that the substrate mounting area 105 must be flat. In general, the substrate mounting area 105 can be flat to conform to a substrate surface that is flat or may have some curvature to conform to a substrate surface that has some curvature.

The geometry and material of the support plate 102 may be selected such that the support plate 102 is sufficiently rigid to prevent warpage of the substrate when mounted on the substrate mounting area 105. In some embodiments, the support plate 102 may be made of stainless steel or other material that will not react with the substrate under substrate processing conditions. The other material may be rendered inert by a suitable coating. Further, the surface mounting area 105 is preferably smooth and free of features that can scratch the surface of the substrate.

Mounting holes 110 may be formed in the support plate 102 to allow the substrate holder 100 to be attached to another fixture, such as a coating drum and the like. In some embodiments, the mounting holes 110 may be recessed through-holes for socket cap screws or tapped on the underside to receive bolt threads.

Referring to FIGS. 1B and 1C, the sidewalls 108A, 108B are located on opposite sides of the support plate 102 and connect to parallel edges 104A, 104B, respectively, of the top surface 104 (or the substrate mounting area 105). In one embodiment, the sidewalls 108A, 108B are beveled. The beveling may be such that the sidewalls 108A, 108B are inclined inwardly, i.e., towards each other, when viewed from the top surface 104. In one embodiment, flat springs 112A, 112B are mounted on the sidewalls 108A, 108B, respectively, in a position to engage opposite side edges of a substrate placed on the substrate mounting area 105. The flat springs 112A, 112B may be secured to the sidewalls 108A, 108B by bolted plates 114A, 114B or other suitable method. In one embodiment, the flat springs 112A, 112B may be of the cantilever type, each having a plurality of finger springs 113A, 113B, respectively. The finger springs are deflectable portions of the cantilever spring that act as springs. FIG. 1D shows an example of a cantilever spring 112A with finger springs 113A. The cantilever spring 112B may have a finger pattern similar to the one shown in FIG. 1D, or both of the cantilever springs 112A, 112B may have other finger patterns known in the art or determined by the amount of spring force required to hold the substrate in place on the substrate mounting area. A cantilever spring may be made by stamping or cutting or slitting a flat strip of material, such as a strip of stainless steel or other malleable material, to form the finger springs in the strip of material. As shown in FIG. 1C, the finger springs 113A, 113B terminate in curved ends 115A, 115B, respectively, which provide the spring tension that will urge the finger springs 113A, 113B against the side edges of the substrate when the substrate is placed on the substrate mounting area 105.

The flat springs 112A, 112B are mounted on the sidewalls 108A, 108B such that the finger springs 113A, 113B protrude above the top surface 104, forming lips 116A, 116B, respectively. The lips 116A, 116B include the curved ends 115A, 115B with the spring tension. The lips 116A, 116B together with the surface mounting area 105 define a slot 117 for receiving a substrate. As shown in FIG. 1E, when the substrate S is inserted into the slot 117 and placed on the surface mounting area 105, the lips 116A, 116B will engage opposite side edges 14 of the substrate S and apply opposing forces to the substrate S, thereby clamping the substrate S to the substrate mounting area 105. The lips 116A, 116B can be pulled back to allow the substrate S to be inserted into the slot 117 and placed on the surface mounting area 105. When the pull force is released, the lips 116A, 116B will engage the adjacent side edges of the substrate S. The same pull back of the lips 116A, 116B can be employed when removing the substrate S from between the lips 116A, 116B. FIG. 1F also shows a substrate S′ received in the slot 117. The main difference between FIGS. 1E and 1F lies in the shape of the side edges 14, 14′ of the substrates S, S′. In FIG. 1E, the side edges 14 are straight. In FIG. 1F, the side edges 14′ are beveled. This shows that the substrate holder 100 can be used with substrates with various side edge profiles. The reference character S will be used to generally refer to any substrate with any side edge profile.

In one embodiment, the flat springs 112A, 112B are mounted on the sidewalls 108A, 108B such that the lips 116A, 116B will extend only partway up the side edges 14 (14′) of the substrate S (S′) when the substrate is mounted on the substrate mounting area 105. That is, the substrate edge contact height h of the flat springs 112A, 112B is selected to be less than the thickness T of the substrate S. (The substrate edge contact height of the flat spring is the height of the portion of the flat spring that will contact the side edge of the substrate or, more simply, the height of the lip formed by the flat spring.) In some embodiments, h is 0.5T or less. By making h less than T, and preferably equal to or less than 0.5T, it will be possible to fully coat the upper portion of the side edges 14 (14′) of the substrate S (S′) while the lips 116A, 116B maintain a grip on the substrate S (S′) by contacting a lower portion of the side edges 14 (14′) and by aid of spring tension. In some applications, such as handheld device applications, the thickness of the substrate S (S′) may be in a range from 50 μm to 2.0 mm. In this case, the contact height of the lips 116A, 116B may be in a range from 25 μm to 1.0 mm.

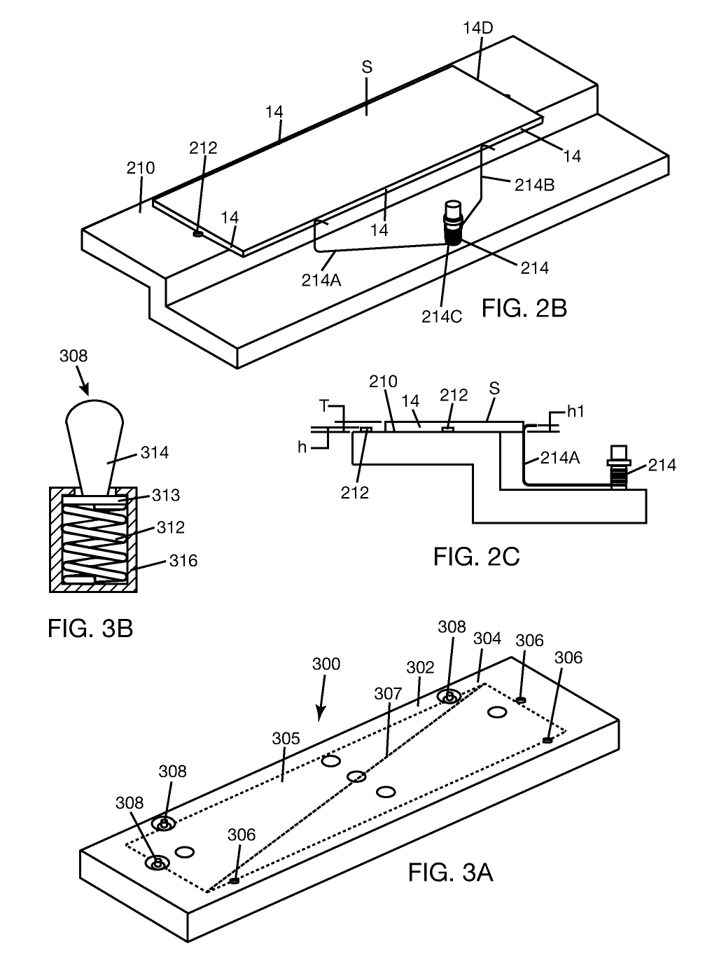

FIG. 2A shows a substrate holder 200 including a support plate 202. The support plate 202 has a stepped structure made of an upper plate section 204 and a lower plate section 206 joined together by a sidewall 208. The upper plate section 204 has a top surface 210, which provides an area 211 for mounting of a substrate. A plurality of contact pins 212 are arranged at the perimeter of the substrate mounting area 211. The contact pins 212 may be inserted into holes formed in the top surface 210 such that the upper ends of the contact pins 212 protrude out of the holes and above the top surface 210 as shown in FIG. 2A. Two or more contact pins 212 may be arranged at the perimeter of the substrate mounting area 211 to engage a substrate mounted on the substrate mounting area 211 at two or more contact points. In the embodiment shown in FIG. 2A, four contact pins 212 are arranged at the perimeter of the substrate mounting area 211 to engage the substrate at four contact points. Preferably, all of these contact points will not be collinear, although some of the points may be collinear.

A torsion spring 214 is mounted on, or coupled to, the lower plate 206. The torsion spring 214 can be mounted on, or coupled to, the lower plate 206 by inserting an upper part of a pin 218 into the core of the torsion spring 214 and inserting a bottom part of the pin 218 into a hole formed in the top surface 216 of the lower plate 206, as shown in FIG. 2A. The pin 218 will serve as both a support for the torsion spring 214 and means of retaining the torsion spring 214 on the lower plate 206. The torsion spring 214 includes a helical spring 214C terminating in legs 214A, 214B. The legs 214A, 214B extend towards the substrate mounting area 211. The legs 214A, 214B will engage a side edge of a substrate when the substrate is mounted on the substrate mounting area 211 and push the substrate against the contact pins 212, thereby clamping the substrate in place on the substrate mounting area 211. The torsion spring 214 can be made of stainless steel or other suitable material that will not react with the substrate under the processing conditions of the substrate.

FIG. 2B shows a substrate S mounted on the substrate mounting area (211 in FIG. 2A) such that the contact pins 212 and the legs 214A, 214B of the torsion spring 214 engage the side edges 14 of the substrate S, thereby clamping the substrate S to the substrate mounting area. To place the substrate S on the substrate mounting area, the legs 214A, 214B can be pulled back, i.e., in a direction away from the substrate mounting area, allowing room to locate the substrate S on the substrate mounting area and in between the contact pins 212. When the pull force is released, the legs 214A, 214B will engage the side edge of the substrate as shown in FIG. 2B.

In one embodiment, as shown in FIG. 2C, the substrate edge contact height h of each contact pin 212 may be selected to be less than a thickness T of the substrate S. The contact height h is the height of the portion of the contact pin 212 that will contact the substrate edge 14. Typically, this would be the height of the portion of the contact pin 212 protruding above the top surface 210, as shown in FIG. 2C. In some embodiments, the height h may be equal to or less than 0.5T. Similarly, the tips of the legs 214A, 214B may be bent back, i.e., in a direction away from the substrate mounting area (211 in FIG. 2A), such that the contact height h1 of each of the legs 214A, 214B is less the thickness T of the substrate S. With the height h and h1 selected as described above, the contact pin 212 and torsion spring legs 214A, 214B can engage a lower portion of the side edges 14 of the substrate S while leaving an upper portion of the side edges 14 of the substrate S uncovered and able to receive a coating. In some applications, such as handheld device applications, the thickness of the substrate S may be in a range from 50 μm to 2.0 mm. In this case, the contact height h, h1 may be in a range from 25 μm to 1.0 mm.

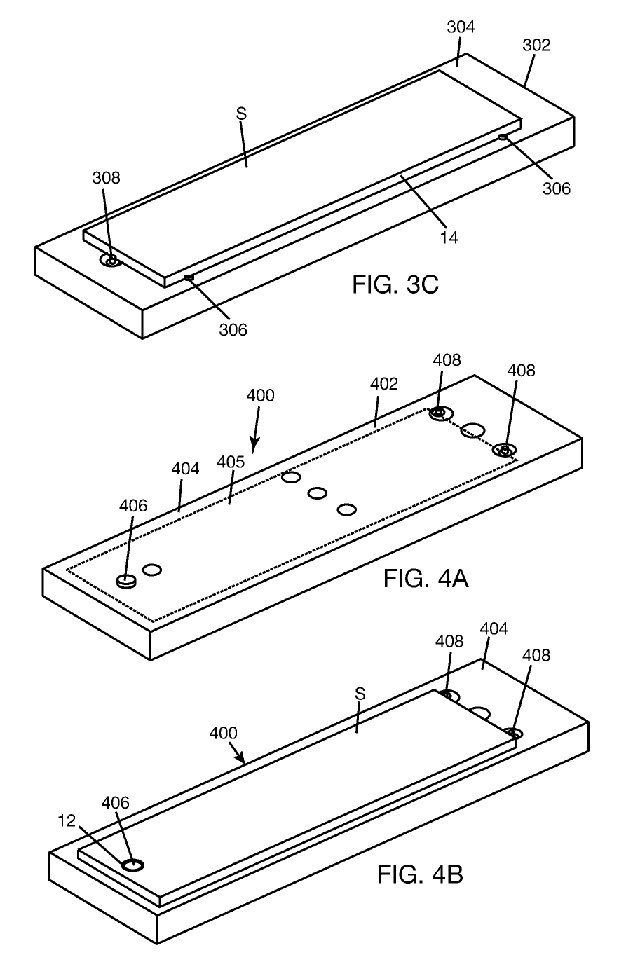

FIG. 3A shows a substrate holder 300 including a support plate 302 having a top surface 304. The top surface 304 provides a substrate mounting area 305. Contact Pins, e.g., dowel pins, 306 are arranged at the perimeter of the substrate mounting area 305 to engage a substrate placed on the substrate mounting area 305. Two or more contact pins 306 may be arranged at the perimeter of the substrate mounting area 305 to engage the substrate placed on the substrate mounting area 305 at two or more contact points. Typically, all of these contact points will not be collinear so that at least two non-parallel side edges of the substrate will be engaged by the contact pins 306. Two or more lateral spring pins 308 are also arranged at the perimeter of the substrate mounting area 305 to engage a substrate placed on the substrate mounting area at two or more contact points. The set of contact pins 306 may be arranged at the perimeter such that it is generally in opposing relation to the set of lateral spring pins 308. The opposition may be along a diagonal line, as shown at 307 in FIG. 3A.

FIG. 3B shows one example of a lateral spring pin 308. In this example, the lateral spring pin 308 includes a helical spring 312 attached to the bottom end of a pin 314. The helical spring 312 may be contained within a body 316, which can be inserted into a hole in the support plate 302 (FIG. 3A) such that the upper end of the pin 314 protrudes above the top surface 304 (FIG. 3A) of the support plate by a desired height. Lateral spring pins are available commercially, such as the K series lateral spring plungers with thrust pins from Kipp Inc. Lateral spring pins may also be referred to as side thrust pins. The lateral spring pin works generally as follows: The helical spring 312 contained in the body 316 presses against a flat disk 313 that is fixed to the bottom of the bowling pin shaped contact pin 314. If the pin 314 makes contact with another component, such as a substrate, the pin 314 tends to tilt off its vertical axis. The spring 312 pressing against the flat disk 313 provides a restoring force that tries to force the pin 314 vertical, and by extension, provides a lateral force against the other component.

FIG. 3C shows a substrate S mounted on the surface mounting area (305 in FIG. 3A) of the support plate 302, with the lateral spring pins 308 and contact pins 306 engaging the substrate S on the side edges 14. The spring tension in the lateral spring pins 308 will apply a force to the substrate that will push the substrate against the contact pins 306, thereby clamping the substrate S to the substrate mounting area. The lateral spring pins 308 can be pulled back to allow room for placing the substrate S on the substrate mounting area or removing the substrate S from the substrate mounting area. When the pull force is released, the lateral spring pins 308 will return to a position in which they can engage the side edges of a substrate mounted on the substrate mounting area.

As in the previous examples, the substrate edge contact height of each of the lateral spring pins 308 and contact pins 306 may be less than a thickness of the substrate S to provide clearance for coating an upper portion of the side edges of the substrate S. In some embodiments, the contact height may be equal to less than half of the thickness of the substrate. In some applications, such as handheld device applications, the thickness of the substrate S may be in a range from 50 μm to 2.0 mm. In this case, the contact height of the lateral spring pins 308 and contact pins 306 may be in a range from 25 μm to 1.0 mm.

FIG. 4A shows a substrate holder 400 including a support plate 402 having a top surface 404. The top surface 404 provides a substrate mounting area 405. Lateral spring pins 408, as described above, are arranged at a perimeter of the substrate mounting area 405. Two lateral spring pins 408 are shown. In general, one or more lateral spring pins 408 may be arranged at the perimeter of the substrate mounting area 405. The lateral spring pins 408 will engage a side edge of a substrate placed on the substrate mounting area 405. A contact pin 406 is located at a distance from the lateral spring pins 408 and within the perimeter of the substrate mounting area 405. The contact pin 406 will fit into a hole in a substrate mounted on the substrate mounting area 405.

FIG. 4B shows a substrate S mounted on the substrate mounting area (405 in FIG. 4A) such that a hole 12 in the substrate S fits over the contact pin 406 and the lateral spring pins 408 engage a side edge of the substrate S. The lateral spring pins 408 can be pulled back to allow room for placing the substrate S on the substrate mounting area. When the pull force is released, the lateral spring pins 408 will engage the side edge of the substrate S and urge the substrate S against the contact pin 406. As in the previous embodiments, the contact height of each of the lateral spring pins 408 may be less than the thickness of the substrate S, and preferably equal to or less than half a thickness of the substrate S. The contact height of the contact pin 406 may also be less than the thickness of the substrate S to ensure that the contact pin 406 will not obstruct coating of the top surface of the substrate S.

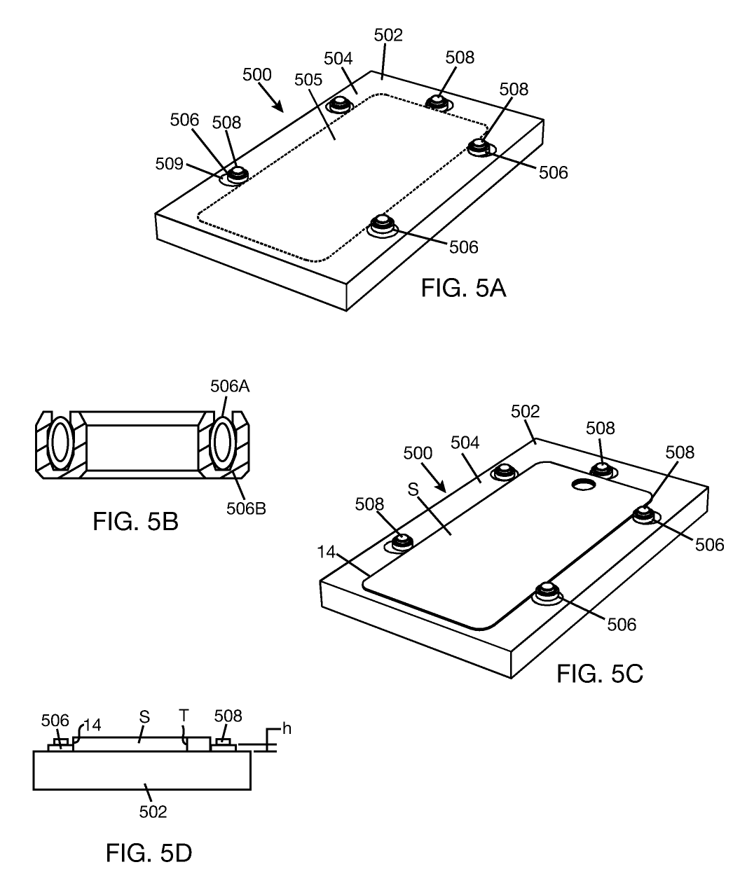

FIG. 5A shows a substrate holder 500 including a support plate 502 having a top surface 504. The top surface 504 provides a substrate mounting area 505. Spring energized seals 506 are arranged at the perimeter of the substrate mounting area 505 to engage side edges of a substrate mounted on the substrate mounting area 505. In one embodiment, the arrangement of the spring energized seals 506 may involve placing the spring energized seals 506 around an upper part of contact pins 508 and inserting a lower part of the contact pins 508 in pin holders 509 embedded in the top surface 504. In one example, as shown in FIG. 5B, each spring energized seal 506 may include a toroid spring 506A mounted in an annular jacket 506B. In alternate embodiments, a cantilevered “U” or “V” spring geometry may be used instead of the toroid spring 506A. The jacket 506B may be made of a polymer material. One suitable polymer material is polytetrafluoroethylene (PTFE), such as sold under the trade name TEFLON® by E. I. du Pont de Nemours and Company. The jacket 506B is the part of the spring energized seal 506 that will contact the substrate edge in the substrate mounting area. Spring energized seals 506 such as shown in FIG. 5B are available commercially, for example, from McMaster-Carr, Atlanta, Ga.

Returning to FIG. 5A, two or more spring energized seals 506 may be arranged at the perimeter of the substrate mounting area 505, where the arrangement is such that there will be no net rotation on the substrate S when the spring energized seals 506 engage the substrate edges. Typically, this means that all of the spring energized seals 506 will not be collinear, although some of the spring energized seals 506 can be collinear. Also, this may mean that at least some of the spring energized seals 506, e.g., at least two of the spring energized seals 506, are arranged at opposed sections of the perimeter, e.g., perimeter sections 505A, 505B, of the substrate mounting area 505, as shown in FIG. 5A.

FIG. 5C shows a substrate S mounted on the substrate mounting area (505 in FIG. 5A). The spring energized seals 506 are pressed between the contact pins 508 and the adjacent substrate side edges 14 when the substrate S is mounted on the substrate mounting area. The spring energized seals 506 are arranged to apply opposing forces to the substrate S, thereby clamping the substrate S to the substrate mounting area. When loading the substrate S on the surface mounting area, the spring energized seals 506 can be compressed against the contact pins 508 to allow sufficient room to drop the substrate S on the surface mounting area. When the compression force is removed, the spring energized seals 506 will expand to engage the substrate edges 14.

Referring to FIG. 5D, the substrate edge contact height h of the spring energized seals 506, which will basically be the height of the spring energized seal 506 for the example shown in FIG. 5B, can be selected to be less than the thickness T of the substrate S. This will allow the spring energized seals 506 to engage the substrate edges 14 in a lower portion of the substrate edges 14, leaving clearance for the upper portion of the substrate edges 14 to be coated. In some embodiments, the contact height h may be equal to or less than half a thickness T of the substrate S. In some applications, such as handheld device applications, the thickness of the substrate S may be in a range from 50 μm to 2.0 mm. In this case, the contact height of the spring energized seal 506 may be in a range from 25 to 1.0 mm.

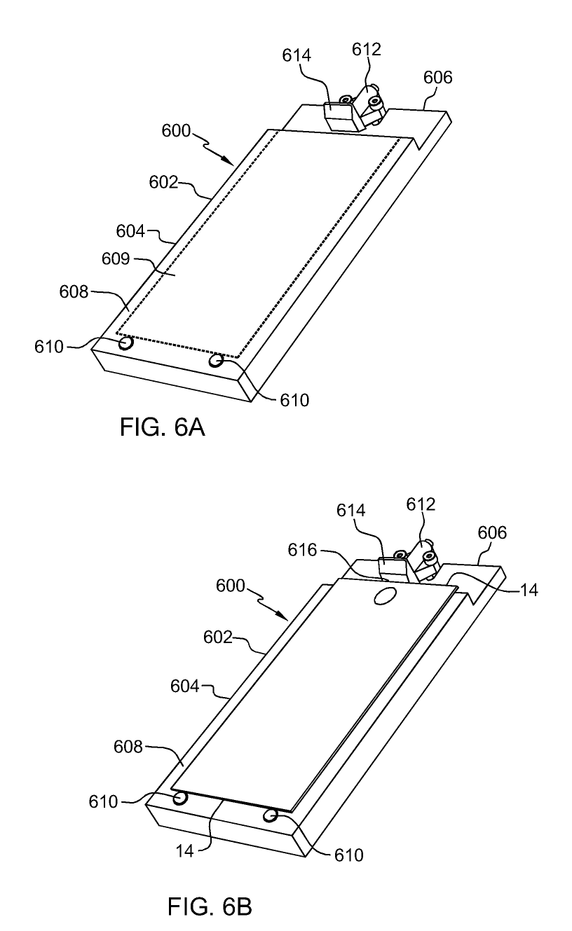

FIG. 6A shows a substrate holder 600 including a support plate 602. The support plate 602 has a stepped structure including an upper plate 604 and a lower plate 606. The upper plate 604 has a top surface 608 that provides a substrate mounting area 609. One or more contact pins 610 may be arranged at a perimeter of the substrate mounting area 609 to engage a side edge of a substrate mounted on the substrate mounting area 609. A spring loaded plunger 612 is mounted on the lower plate 606. The plunger face 614 of the spring loaded plunger 612 extends towards the substrate mounting area 609 and is in opposed relation to the contact pins 610. Spring loaded plungers are available commercially. One suitable example is Spring Stop DS-5 from Essentra Components, IL.

FIG. 6B shows a substrate S on the substrate mounting area (609 in FIG. 6A). The spring loaded plunger 612 engages a side edge 14 of the substrate S via the plunger face 614 and pushes the substrate S against the contact pins 610, thereby clamping the substrate S to the substrate mounting area. The plunger face 614 can be initially pushed back to allow loading of the substrate S on the substrate mounting area 609. When the push force is removed, the spring loaded plunger 612 will engage and apply a force to the side edge 14 of the substrate S as shown in FIG. 6B.

As in the previous examples, the contact height of the contact pins 610 may be selected to be less than the height of the substrate S such that the contact pins do not cover the upper portion of the side edges of the substrate S. In some embodiments, the contact height may be selected to be equal to half or less of the thickness of the substrate S. Typically, the diameter or height of the plunger face 614 will be larger than the thickness of the substrate. Therefore, the spring loaded plunger 612 may prevent coating of a small area 616 of the substrate side edge 14 where the plunger face 614 contacts the side edge.

In the embodiments described above where contact pins are used, such as in FIGS. 2B, 3B, 4B, and 6B, there may be force loading on the substrate edges where the pins contact the substrate edges. Typically, the contact pins will be metal pins with a round cross-section. To avoid substrate failure due to point loading on the substrate edges when using these pins, it is desirable to have the surfaces of the pins contacting the substrate edges made from a polymeric material. For example, polymeric sleeves can be fitted around the portions of the pins that would come into contact with the substrate edges. Polymeric coatings may also be used in place of polymeric sleeves for the same purpose described above.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

1. A substrate holder, comprising:
a support plate having a substrate mounting area on which a substrate having a select thickness may be mounted; and
at least two spring members coupled to the support plate such that at least a portion of the substrate mounting area is between the two spring members;
wherein the two spring members are arranged relative to the substrate mounting area to engage side edges of the substrate and apply opposing forces to the substrate when the substrate is mounted on the substrate mounting area.

2. The substrate holder of claim 1, wherein the two spring members are flat springs.

3. The substrate holder of claim 2, wherein the support plate comprises two beveled sidewalls, wherein the substrate mounting area is located between the two beveled sidewalls, and wherein the two flat springs are mounted on the two beveled sidewalls, respectively.

4. The substrate holder of claim 2, wherein each of the flat springs comprises a plurality of finger springs for engaging the side edges of the substrate.

5. The substrate holder of claim 4, wherein the finger springs terminate in curved ends.

6. The substrate holder of claim 1, wherein the two spring members are spring energized seals, and wherein the spring energized seals are distributed along a perimeter of the substrate mounting area to engage the side edges of the substrate and apply opposing forces to the substrate when the substrate is mounted on the substrate mounting area.

7. The substrate holder of claim 6, further comprising at least one additional spring energized seal, wherein the spring energized seals are distributed along the perimeter of the substrate mounting area to engage the side edges of the substrate and apply opposing forces to the substrate when the substrate is mounted on the substrate mounting area.

8. The substrate holder of claim 1, wherein a substrate edge contact height of each spring member is less than a thickness of the substrate.

9. The substrate holder of claim 1, wherein the substrate mounting area has a flatness in a range from 0.0005 inch to 0.001 inch TIR.

10. A substrate holder, comprising:
a support plate having a substrate mounting area on which a substrate having a select thickness may be mounted;
a spring member coupled to the support plate; and
a contact pin coupled to the support plate such that at least a portion of the substrate mounting area is between the spring member and the contact pin;
wherein the spring member and the contact pin are arranged relative to the substrate mounting area to engage side edges of the substrate and apply opposing forces to the substrate when the substrate is mounted on the substrate mounting area.

11. The substrate holder of claim 10, wherein the spring member is a torsion spring having a pair of legs extending laterally towards the substrate mounting area.

12. The substrate holder of claim 11, wherein the support plate has a stepped structure comprising an upper plate and a lower plate, and wherein the substrate mounting area is located on the upper plate and the spring member is located on the lower plate.

13. The substrate holder of claim 10, further comprising at least one additional contact pin coupled to the support plate, wherein the contact pins are distributed along a perimeter of the substrate mounting area such that the force applied to the substrate by the spring member will be opposed by the forces applied to the substrate by the contact pins when the substrate is mounted on the substrate mounting area.

14. The substrate holder of claim 10, wherein the spring member is a lateral spring pin, and wherein the lateral spring pin and contact pin are distributed along a perimeter of the substrate mounting area to engage and apply opposing forces to the side edges of the substrate when the substrate is mounted on the substrate mounting area.

15. The substrate holder of claim 14, further comprising at least one additional contact pin and at least one additional lateral spring pin coupled to the support plate, wherein the contact pins and lateral spring pins are distributed along the perimeter of the substrate mounting area to engage the side edges of the substrate and apply opposing forces to the substrate when the substrate is mounted on the substrate mounting area.

16. The substrate holder of claim 15, wherein the lateral springs are arranged in opposing relation to the contact pins along a diagonal line of the substrate mounting area.

17. The substrate holder of claim 10, wherein the spring member is a lateral spring pin disposed along a perimeter of the substrate mounting area to engage an outer side edge of the substrate, and wherein the contact pin is disposed within the perimeter of the substrate mounting area to engage an inner side edge of the substrate.

18. The substrate holder of claim 17, further comprising at least one additional lateral spring pin disposed along the perimeter of the substrate mounting area to engage the external side edge of the substrate.

19. The substrate holder of claim 10, wherein the spring member is a spring loaded plunger, and wherein the spring loaded plunger is coupled to the support plate, such that a plunger face of the spring loaded plunger extends towards the substrate mounting area and in opposing relation to the contact pin.

20. The substrate holder of claim 10, wherein a substrate edge contact height of each of the spring member and contact pin is less than the select thickness of the substrate.
